(19) United States
(12) Patent Application Publication
(10) Pub. No.: US 2016/0139648 A1
(43) Pub. Date: May 19, 2016

(54) INTERFACE SUPPLY CIRCUIT

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: JIE MIN, Wuhan (CN); CHUN-SHENG CHEN, New Taipei (TW)

(21) Appl. No.: 14/610,080

(22) Filed: Jan. 30, 2015

(30) Foreign Application Priority Data
Nov. 13, 2014 (CN) 201410639142.2

(51) Int. Cl. G06F 1/32; H03K 17/687

(52) U.S. Cl. CPC G06F 1/3246; H03K 17/6871

(57) ABSTRACT

An interface supply circuit includes an interface, a control circuit coupled to the interface, a power supply coupled to the control circuit, a control chip coupled to the power supply, and a detection chip coupled to the control chip and the interface. The power supply supplies power to the interface. The interface is configured to receive a wireless card. The detection chip is configured to detect a working state of a computer and detect whether the wireless card is inserted into the interface. The detection chip sends a stop signal to the control chip upon detecting that the computer is shutdown and that no wireless card is inserted into the interface. The control chip sends a disconnect signal to the control circuit upon receiving the stop signal. The control circuit disconnects the power supply and the interface upon receiving the disconnect signal.

### CROSS-REFERENCE TO RELATED APPLICATIONS

This application claims priority to Chinese Patent Application No. 201410639142.2 Nov. 13, 2014, the contents of which are incorporated by reference herein.

### FIELD

The subject matter herein generally relates to power conservation.

### BACKGROUND

An interface supply circuit may be used to decrease power consumption.

### BRIEF DESCRIPTION OF THE DRAWINGS

Implementations of the present technology will now be described, by way of example only, with reference to the attached figures.

FIG. 1 is a block diagram of one embodiment of an interface supply circuit.

FIG. 2 is a circuit diagram of the interface supply circuit of FIG. 1.

FIG. 3 is a flowchart of one embodiment of the interface supply circuit.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

The present disclosure is described in relation to an interface supply circuit used to decrease power consumption.

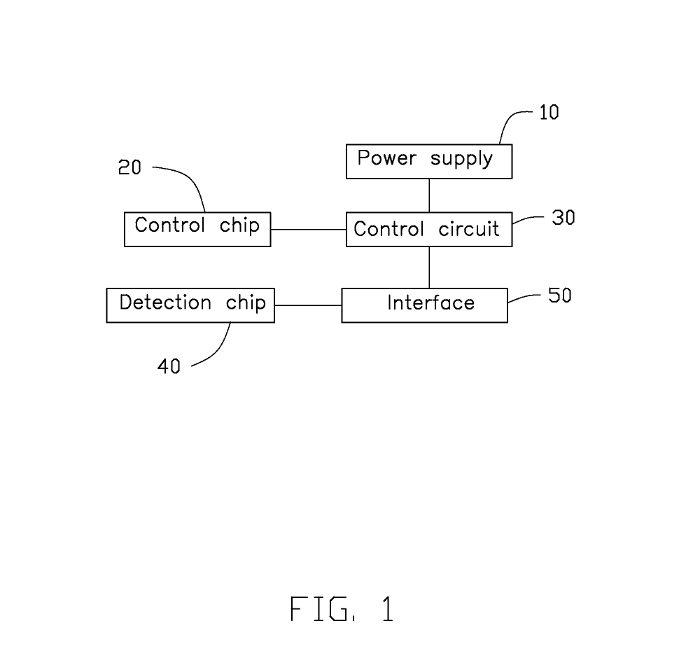

FIG. 1 illustrates an embodiment of an interface supply circuit. The interface supply circuit comprises a power supply 10, a control chip 20 coupled to the power supply 10, a control circuit 30 coupled to the control chip 20, a detection chip 40 coupled to the control chip 20, and an interface 50 coupled to the detection chip 40. The power supply 10 is configured to supply power to the interface 50. In one embodiment, the control chip 20 is an embedded controller (EC), and the interface 50 is a Mini PCI-E interface and is configured to receive a plurality of hardware devices, such as BLUETOOTH® adapters, video cards, wireless cards, and solid state hard drives.

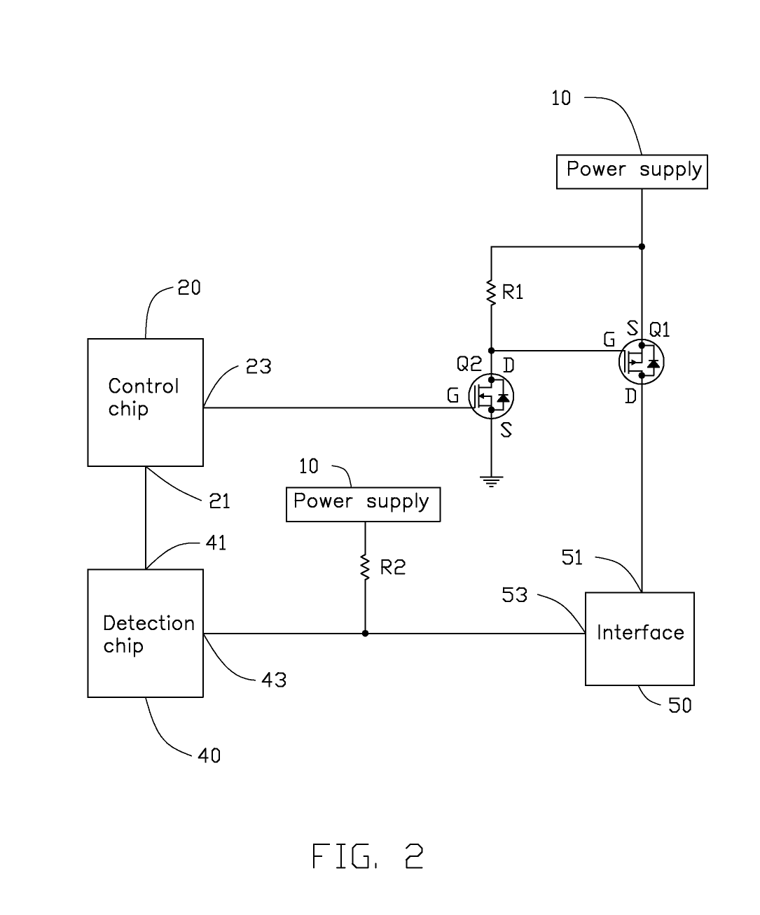

FIG. 2 illustrates that, in at least one embodiment, the detection chip 40 is a north bridge chip. The detection chip 40 is configured to output different level signals according to a working state of a computer. The working state of the computer comprises a normal state (S0 state) and a shutdown state (S5 state). The detection chip 40 comprises a connecting terminal 41 and a detection terminal 43.

The control chip 20 comprises a connecting pin 21 and a control pin 23.

The control circuit 30 comprises a first field effect transistor (FET) Q1 and a second FET Q2. In one embodiment, the first FET Q1 is a P-channel MOSFET and the second FET Q2 is a N-channel MOSFET.

The interface 50 comprises a power supply pin 51 and a detection pin 53.

The power supply 10 coupled to a source terminal S of the first FET Q1. The power supply 10 is coupled to a drain terminal D of the second FET Q2 via a first resistor R1. A gate terminal G of the first FET Q1 is coupled to a drain terminal D of the second FET Q2. A drain terminal D of the first FET Q1 is coupled to the power supply pin 51 of the interface 50. A source terminal S of the second FET Q2 is grounded. Agate terminal G of the second FET Q2 is coupled to the control pin 23 of the control chip 20. The connecting pin 21 of the control chip 20 is coupled to the connecting terminal 41 of the detection chip 40. The detection terminal 43 of the detection chip 40 is coupled to the detection pin 53 of the interface 50. The detection terminal 41 of the detection chip 40 is coupled to the power supply 10 via a second resistor R2.

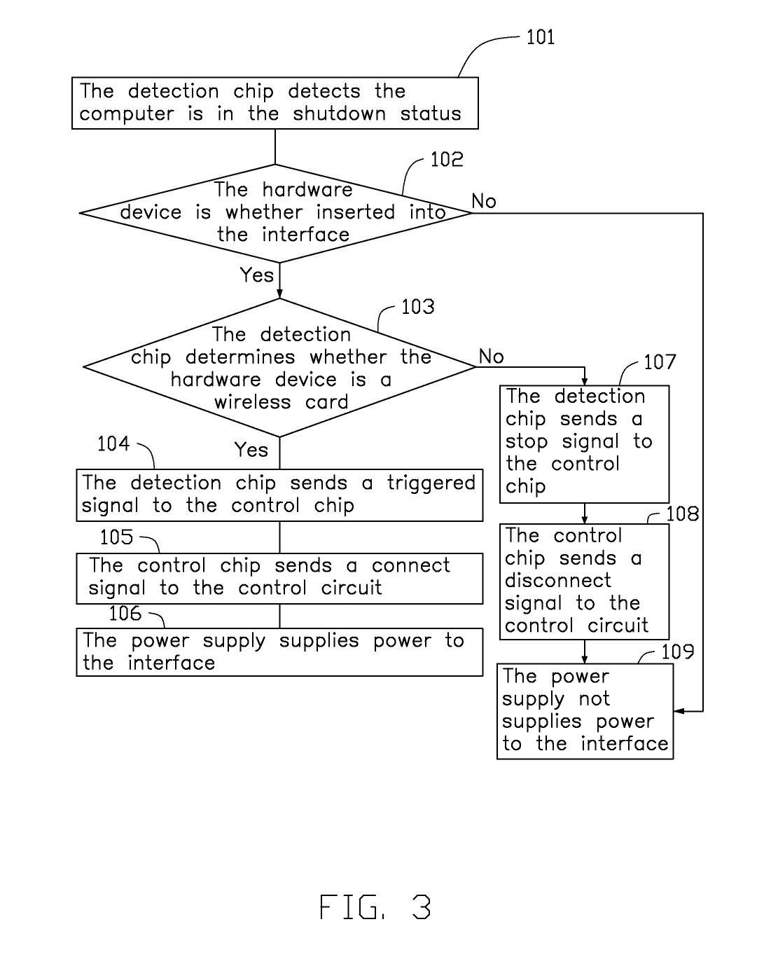

FIG. 3 illustrates a flowchart in accordance with an example embodiment. A method of the interface supply circuit is provided by way of example, as there are a variety of ways to carry out the method. The method of the interface supply circuit described below can be carried out using the configurations illustrated in FIGS. 1 and 2, for example, and various elements of these figures are referenced in explaining method of the interface supply circuit. In FIG. 3 each block represents one or more processes, methods, or subroutines carried out in method of the interface supply circuit. Additionally, the illustrated order of blocks is by example only and the order of the blocks can change. The method of the interface supply circuit can begin at block 101.

At block 101, the detection chip 40 detects the computer is shutdown.

At block 102, the detection chip 40 determines whether the hardware device is inserted into the interface 50, if yes, the method goes to block 103; if no, the method goes to block 109.

At block 103, the detection chip 40 determines whether the hardware device is a wireless card, if yes, the method goes to block 105; if no, the method goes to block 107.

At block 104, the detection chip 40 sends a triggered signal to the control chip 20.

At block 105, the control chip 20 sends a connect signal to the control circuit 30.

At block 106, the power supply 10 supplies power to the interface 50.

At block 107, the detection chip 40 sends a stop signal to the control chip 20.

At block 108, the control chip 20 sends a disconnect signal to the control circuit 30.

At block 109, the power supply 10 does not supply power to the interface 50.

In the interface supply circuit, the detection chip 40 sends the stop signal to the control chip 20, when the computer is shutdown and the detection chip 40 detects no wireless card is inserted into the interface 50. The control chip 20 sends the disconnect signal to the control circuit 30 after receiving the stop signal, thereby the second FET Q2 is switched off after which the first FET Q1 is switched off. The power supply 10 does not supply power to the interface 50, thus decreasing the power consumption. In one embodiment, the connect signal is a high level signal, the disconnect signal is a low level signal.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure to the full extent indicated by the broad general meaning of the terms in which the appended claims are expressed.

What is claimed is:

1. An interface supply circuit comprising:
a control circuit couplable to an interface;
a power supply configured to supply power to the interface;
a control chip coupled to the power supply, and
a detection chip coupled to the control chip;
wherein the interface is configured to receive a wireless card;
wherein the detection chip is configured to detect a working state of a computer and detect whether the wireless card is inserted into the interface;
wherein the detection chip is configured to send a stop signal to the control chip upon detecting that the computer is shutdown and that the wireless card is not inserted into the interface;
wherein the control chip is configured to send a disconnect signal to the control circuit upon receiving the stop signal, and
wherein the control circuit is configured to disconnect the power supply and the interface upon receiving the disconnect signal.

2. The interface supply circuit of claim 1, wherein the control circuit comprises a first field effect transistor (FET), the first FET is coupled to the power supply, and the first FET is switched off after the control circuit receives the disconnect signal.

3. The interface supply circuit of claim 2, wherein the control circuit further comprises a second FET, the control chip is coupled to the second FET, the second FET is coupled to the first FET, the second FET is switched off after receiving the disconnect signal, and the first FET is switched off after the second FET is switched off.

4. The interface supply circuit of claim 3, wherein the second FET is a N-channel MOSFET.

5. The interface supply circuit of claim 3, wherein the first FET is a P-channel MOSFET.

6. The interface supply circuit of claim 5, wherein the power supply is coupled to a source terminal of the first FET and a drain terminal of the second FET, a gate terminal of the first FET is coupled to the drain terminal of the second FET, a drain terminal of the first FET is coupled to the interface, a gate terminal of the second FET is coupled to the control chip.

7. The interface supply circuit of claim 1, wherein the control chip is an embedded controller.

8. The interface supply circuit of claim 1, wherein the detection chip is a north bridge chip.

9. The interface supply circuit of claim 8, wherein the interface is a Mini PCI-E interface.

10. The interface supply circuit of claim 1, wherein the detection chip is configured to send a triggered signal to the control chip after detecting the computer is shutdown and detecting the wireless card is inserted into the interface, the control chip is configured to send a connect signal to the control circuit after receiving the triggered signal, and the control circuit is switched on after receiving the connect signal, thereby the power supply supplies power to the interface.

11. An interface supply circuit comprising:
an interface configured to receive a wireless card;
a control circuit coupled to the interface;
a power supply coupled to the control circuit and configured to supply power to the interface;
a control chip coupled to the power supply, and
a detection chip coupled to the control chip and the interface;
wherein the detection chip is configured to detect a working state of a computer and detect whether the wireless card is inserted into the interface;
wherein the detection chip is configured to send a stop signal to the control chip upon detecting that the computer is shutdown and that no wireless card is inserted into the interface;
wherein the control chip is configured to send a disconnect signal to the control circuit upon receiving the stop signal, and
wherein the control circuit is configured to disconnect the power supply and the interface upon receiving the disconnect signal.

12. The interface supply circuit of claim 11, wherein the control circuit comprises a first field effect transistor (FET), the first FET is coupled to the power supply and the interface, and the first FET is switched off after the control circuit receives the disconnect signal, thereby the power supply disconnects to the interface.

13. The interface supply circuit of claim 12, wherein the control circuit further comprises a second FET, the control chip is coupled to the second FET, the second FET is coupled to the first FET, the second FET is switched off after receiving the disconnect signal, and the first FET is switched off after the second FET is switched off.

14. The interface supply circuit of claim 13, wherein the first FET is a P-channel MOSFET.

15. The interface supply circuit of claim 14, wherein the power supply is coupled to a source terminal of the first FET and a drain terminal of the second FET, a gate terminal of the first FET is coupled to the drain terminal of the second FET, a drain terminal of the first FET is coupled to the interface, a gate terminal of the second FET is coupled to the control chip.

16. The interface supply circuit of claim 11, wherein the detection chip is a north bridge chip.

17. The interface supply circuit of claim 11, wherein the interface is a Mini PCI-E interface.

18. The interface supply circuit of claim 11, wherein the detection chip is configured to send a triggered signal to the control chip after detecting the computer is shutdown and detecting the wireless card is inserted into the interface, the control chip is configured to send a connect signal to the control circuit after receiving the triggered signal, and the control circuit is switched on after receiving the connect signal, thereby the power supply supplies power to the interface.

19. The interface supply circuit of claim 18, wherein the connect signal is a high level signal.

20. The interface supply circuit of claim 11, wherein the disconnect signal is a low level signal.
